(19) United States
(12) Patent Application Publication
(10) Pub. No.: US 2025/0323624 A1
(43) Pub. Date: Oct. 16, 2025

(54) BULK ACOUSTIC WAVE (BAW) PACKAGE AND METHOD OF MANUFACTURING BAW PACKAGE

(71) Applicant: WISOL CO., LTD., Gyeonggi-do (KR)

(72) Inventors: Chul Hwa LEE, Gyeonggi-do (KR); Jun Ho Kim, Gyeonggi-do (KR); Hyung Joon Yoo, Gyeonggi-do (KR)

(21) Appl. No.: 19/172,854

(22) Filed: Apr. 8, 2025

(30) Foreign Application Priority Data
Apr. 16, 2024 (KR) 10-2024-0050499

(51) Int. Cl. H03H 9/54; H03H 3/02

(52) U.S. Cl. CPC H03H 9/54; H03H 3/02

(57) ABSTRACT

A bulk acoustic wave (BAW) package according to an embodiment of the present invention includes: a BAW filter including a substrate having at least one cavity on an upper surface thereof, a lower electrode formed above the substrate, a piezoelectric layer formed above the lower electrode, and an upper electrode formed above the piezoelectric layer; and a package structure formed above the BAW filter to protect the BAW filter, wherein the package structure includes a wall layer extending in a vertical direction to surround a peripheral portion of the BAW filter; a first roof layer having a plate-shaped structure formed in a horizontal direction on an upper portion of the wall layer; a second roof layer formed to surround a lateral portion of the wall layer and an upper portion of the first roof layer; and a redistribution layer formed on one side of the second roof layer to electrically connect the package structure and the BAW filter.

### CROSS-REFERENCE TO RELATED APPLICATION

This application claims priority from Korean Patent Application No. 10-2024-0050499 filed on Apr. 16, 2024 in the Korean Intellectual Property Office, the contents of which in its entirety are herein incorporated by reference.

### FIELD

The present invention relates to a bulk acoustic wave (BAW) filter and a technique for manufacturing the same.

### BACKGROUND

Wireless mobile communication technology requires a variety of radio frequency (RF) components capable of efficiently transmitting information within a limited frequency band. In particular, among the RF components, a filter, which is one of the key components used in mobile communication technology, enables high-quality communication by selecting the signal required by a user from among countless airwaves or by filtering the signal intended for transmission.

Currently, the RF filters most widely used for wireless communication are dielectric filters and surface acoustic wave (SAW) filters. Dielectric filters are advantages such as high dielectric permittivity, low insertion loss, stability at high temperatures, and high resistance to vibration and shock. However, dielectric filters face limitations in terms of miniaturization and integration into Monolithic Microwave Integrated Circuits (MMICs), which are recent trends in technological development. In addition, compared to dielectric filters, SAW filters are compact, facilitate easier signal processing, and have simpler circuitry; furthermore, by employing semiconductor processes, they offer the advantage of mass production. Moreover, SAW filters exhibit higher side rejection within the passband compared to dielectric filters, which enables the transmission and reception of high-grade information. However, since the SAW filter process includes a light exposure step using ultraviolet (UV) rays, it has the drawback that the line width of an interdigital transducer (IDT) is limited to about 0.5 μm. Therefore, there is a problem that it is not possible to cover the ultra-high frequency (UHF) band (5 GHZ and above) using an SAW filter, and it is fundamentally difficult to configure an MMIC structure or a single chip on a semiconductor substrate.

To overcome the above limitations and issues, a bulk acoustic resonator (BAR) filter capable of completely making a frequency control circuit an MMIC by being integrated with other active elements on the existing silicon (Si) or gallium arsenide (GaAs) substrate has been provided.

BAW filters are thin film devices which feature a low-cost, a small size, and a high quality (high Q) coefficient, making them suitable for use in various wireless communication devices, military radar systems, and the like across a wide frequency range (900 MHz to 10 GHZ). Also, the BAW filters can be miniaturized to a size hundreds of times smaller than dielectric filters or lumped constant (LC) filters and have significantly lower insertion loss compared to SAW filters. Therefore, the BAW filters may be the most suitable devices for MMIC applications that require high stability and high-quality factors.

A BAW filter is fabricated by depositing a piezoelectric dielectric material such as zinc oxide (ZnO) or aluminum nitride (AIN) onto a semiconductor substrate, such as silicon (Si) or gallium arsenide (GaAs), using RF sputtering, and causes resonance due to the piezoelectric properties. Specifically, in a BAW filter, a piezoelectric thin film is deposited between two electrodes, and bulk acoustic waves are generated to induce resonance.

Traditionally, to protect such BAW filters from the external environment, wafer bonding has been used for packaging by joining a filter wafer (device) and a protective wafer (cap) using a metal material at the bonding interface.

This package structure requires a large thickness due to the use of two wafers, silicon holes formed in the protective wafer for the formation of a redistribution layer, and a large bonding layer area for bonding with the device wafer. As a result of this structure, the size and thickness of the device increase. Additionally, because the metal formation process for bonding and the formation of a silicon via layer for the redistribution layer are required, the number of process steps increases, making the manufacturing process more complex.

In particular, conventional BAW filters are manufactured through wafer bonding using metal materials at the bonding interface between the filter wafer (device) and the protective wafer (cap) to protect the resonator portion from the external environment. The conventional structure requires a large thickness due to the use of two wafers, silicon holes formed in the protective wafer for the formation of the redistribution layer, and a large bonding layer area for bonding with the device wafer. Consequently, the size and thickness of the device increase. Additionally, because the metal formation process for bonding and the formation of a silicon via layer for the redistribution layer are required, the number of process steps increases, making the manufacturing process more complex.

### PRIOR ART DOCUMENT

### Patent Document

(Patent Document 0001) Korean Laid-open Patent Publication No. 10-2004-0102390 (Published on Dec. 8, 2004)

### SUMMARY

### Technical Problem

An objective of the present invention is to provide a BAW package and a method of manufacturing a BAW package, which simplify the packaging process of a BAW filter and enable the formation of a smaller package size.

### Technical Solution

A bulk acoustic wave (BAW) package according to an embodiment of the present invention includes: a BAW filter including a substrate having at least one cavity on an upper surface thereof, a lower electrode formed above the substrate, a piezoelectric layer formed above the lower electrode, and an upper electrode formed above the piezoelectric layer; and a package structure formed above the BAW filter to protect the BAW filter, wherein the package structure includes a wall layer extending in a vertical direction to surround a peripheral portion of the BAW filter; a first roof layer having a plate-shaped structure formed in a horizontal direction on an upper portion of the wall layer; a second roof layer formed to surround a lateral portion of the wall layer and an upper portion of the first roof layer; and a redistribution layer formed on one side of the second roof layer to electrically connect the package structure and the BAW filter.

The wall layer, the first roof layer, and the second roof layer may each be formed of a photosensitive polymer.

The wall layer may include a partition wall extending in the vertical direction on an upper portion of the upper electrode.

The BAW package may further include a reinforcement layer formed between the first roof layer and the second roof layer and configured to support the first roof layer and the second roof layer.

The redistribution layer may be formed on one side of the second roof layer and may connect an electrode pad formed on the BAW filter and an upper portion of the second roof layer.

A method of manufacturing a BAW package according to another embodiment of the present invention includes: forming a glass wafer; forming a release layer above the glass wafer; forming a first roof layer above the release layer; forming a wall layer that extends vertically along end portion of the roof layer and surrounds the first roof layer, thereby completing a package structure; coupling the package structure to a BAW filter that comprises a substrate, a lower electrode, a piezoelectric layer, and an upper electrode; removing the glass wafer and the release layer from the package structure; forming a second roof layer to surround a lateral portion of the wall layer and an upper portion of the first roof layer; and forming a redistribution layer for electrically connecting the package structure and the BAW filter.

The wall layer, the first roof layer, and the second roof layer may each be formed of a photosensitive polymer.

The forming of the wall layer may include forming a partition wall that extends in the vertical direction on an upper portion of the upper electrode.

The method may further include forming a reinforcement layer above the first roof layer to support the first roof layer and the second roof layer after removing the glass wafer and the release layer from the package structure.

The forming of the redistribution layer may include forming the redistribution layer on one side of the second roof layer wherein the redistribution layer connects an electrode pad formed on the BAW filter and an upper portion of the second roof layer.

### Effects of the Invention

According to the present invention, to package a bulk acoustic wave (BAW) filter, a package structure is separately fabricated and then coupled to the BAW filter, thereby simplifying the manufacturing process of a BAW package and enabling the formation of a smaller BAW package compared to conventional packages.

In particular, in the present invention, by forming dual roof layers (a first roof layer and a second roof layer) to package the BAW filter, the package structure can robustly protect the BAW filter from the external environment. Additionally, by further forming a reinforcement layer between the first roof layer and the second roof layer, the rigidity of the roof layers and the wall layer of the BAW package can be improved.

### BRIEF DESCRIPTION OF THE DRAWINGS

FIG. 1 is a cross-sectional side view of a bulk acoustic wave (BAW) package according to an embodiment of the present invention.

FIG. 2 is a flowchart illustrating one embodiment of a method of manufacturing a BAW package according to the present invention.

FIG. 3 illustrates the step-by-step structures of a BAW package formed through the manufacturing method shown in FIG. 2.

FIG. 4 is a cross-sectional side view illustrating a BAW package according to another embodiment of the present invention.

FIG. 5 is a flowchart illustrating another embodiment of a method of manufacturing a BAW package according to the present invention.

FIG. 6 illustrates the step-by-step structures of a BAW package formed through the manufacturing method shown in FIG. 5.

FIG. 7 is a flowchart illustrating another embodiment of a method of manufacturing a BAW package according to the present invention.

FIG. 8 illustrates step-by-step structures of a BAW package formed through the manufacturing method shown in FIG. 7.

FIG. 9 illustrates a BAW package formed by the manufacturing method shown in FIG. 7.

FIG. 10 is a flowchart illustrating still another embodiment of a method of manufacturing a BAW package according to the present invention.

FIG. 11 illustrates step-by-step structures of a BAW package formed through the manufacturing method shown in FIG. 10.

FIG. 12 illustrates a BAW package formed by the manufacturing method shown in FIG. 10.

### DETAILED DESCRIPTION

Hereinafter, exemplary embodiments of the present invention will be described in detail with reference to the accompanying drawings.

The embodiments of the present invention are provided to more completely explain the present invention to one of ordinary skill in the art. The embodiments of the present invention may be changed in a variety of shapes, and the scope of the present invention is not limited to the following embodiments. Rather, these embodiments are provided to make the present disclosure more substantial and complete and to completely transfer the concept of the present invention to those skilled in the art.

The terms used herein are to explain particular embodiments and not intended to limit the present invention. As used herein, singular forms may include plural forms unless particularly defined otherwise in context. Also, as used herein, the term “and/or” includes any and all combinations or one of a plurality of associated listed items.

In addition, in the drawings, like reference numerals denote like elements, and the thickness, the ratio, and the dimensions of constituent elements may be exaggerated for effective explanation of technical contents in the drawings. In addition, hereinafter, the embodiments of the present invention will be described with reference to the drawings which schematically illustrate the embodiments of the present invention.

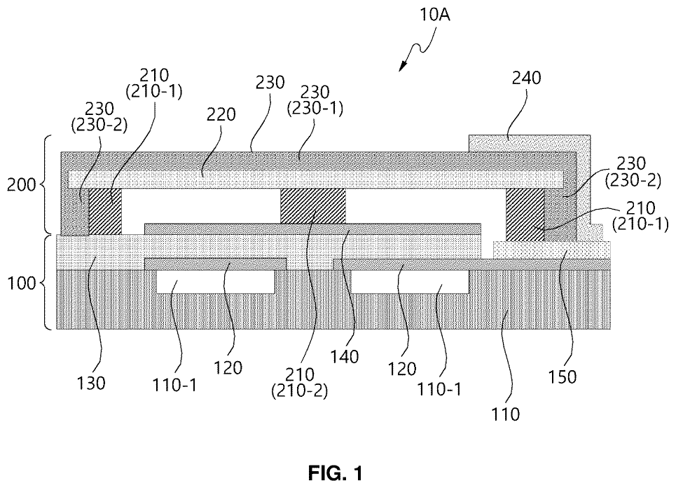

FIG. 1 is a cross-sectional side view of a bulk acoustic wave (BAW) package 10A according to an embodiment of the present invention.

Referring to FIG. 1, a BAW package 10A includes a BAW filter 100 and a package structure 200.

The BAW filter 100 includes a substrate 110, a lower electrode 120, a piezoelectric layer 130, an upper electrode 140, and an electrode pad 150.

When an external signal is applied between the lower electrode 120 and the upper electrode 140, a portion of electrical energy transferred between the two electrodes is converted into mechanical energy due to the piezoelectric effect and is then converted back into electrical energy. During this process, the BAW filter 100 resonates at the natural oscillation frequency depending on the thickness of the piezoelectric layer 130.

The substrate 110, which is a semiconductor substrate, may be a general silicon wafer, and preferably a high resistivity silicon (HRS) substrate. An insulating layer (not shown) may be formed on an upper surface of the substrate 110. The insulating layer may employ a thermal oxide film that can be easily grown on the substrate 110 or may selectively employ an oxide film or nitride film formed by conventional deposition processes such as chemical vapor deposition. Also, the substrate 110 includes at least one cavity 110-1 on its upper surface.

The lower electrode 120 is formed above the substrate 110 and may have a structure where it is entirely covered by the piezoelectric layer 130 or only partially covered. The lower electrode 120 may be formed above the cavity 110-1 in the substrate 110 and may completely or partially surround the upper portion of the cavity 110-1. The lower electrode 120 is formed by depositing a certain material on an upper portion of the substrate 110 and then patterning it. The material used for the lower electrode 120 is a typical conductive material such as metal, and preferably one of aluminum (Al), tungsten (W), gold (Au), platinum (Pt), nickel (Ni), titanium (Ti), chromium (Cr), palladium (Pd), or molybdenum (Mo) may be used.

The piezoelectric layer 30 is formed above the lower electrode 120 and/or the substrate 110. The piezoelectric layer 130 may be formed by depositing a piezoelectric material on the upper portion of the lower electrode 120 and then patterning it. When the piezoelectric layer 130 is formed above the lower electrode 120, it may completely cover the lower electrode 120 or partially cover it. Accordingly, the lower electrode 120 may have both a fully covered portion and a partially covered portion by the piezoelectric layer 130.

The piezoelectric material may be aluminum nitride (AlN) or zinc oxide (ZnO). The deposition method may include an RF magnetron sputtering method, an evaporation method, and the like.

The upper electrode 140 is formed above the piezoelectric layer 130. The upper electrode 140 may be formed by depositing and patterning a metal film for the upper electrode on the upper portion of the piezoelectric layer 130. The upper electrode 140 may be made of the same material as the lower electrode 120 and may be formed using the same deposition and patterning methods as the lower electrode 120.

The electrode pad 150 is formed above the lower electrode 120. The electrode pad 150 is a layer for electrical connection with the package structure 200, and may be formed of a conductive metal material for this purpose.

The package structure 200 is a structure that serves to protect the BAW filter 100. To this end, the package structure 200 includes a wall layer 210, a first roof layer 220, a second roof layer 230, and a redistribution layer 240.

The wall layer 210 is disposed above the BAW filter 100, and extends in a vertical direction to surround the peripheral portion of the BAW filter 100 and forming an outer wall.

The wall layer 210 may be in the form of an outer wall that is formed in the vertical direction from the upper portion of the piezoelectric layer 130 or the electrode pad 150 of the BAW filter 100. In addition, the wall layer 210 may be in the form of a partition wall that is formed in the vertical direction from the upper portion of the upper electrode 140 of the BAW filter 100.

As shown in FIG. 1, the wall layer 210 may be in the form of an outer wall 210-1 that extends in the vertical direction from one lateral portion of the piezoelectric layer 130 or from the upper portion of the electrode pad 150 to surround the BAW filter 100, or in the form of a partition wall 210-2 that extends vertically from the upper portion of the top electrode 140.

The minimum height of the wall layer 210 may be set such that the upper electrode 140, which moves in response to the vibration of the piezoelectric layer 130, does not come into contact with the first roof layer 220. The wall layer 210 may be formed of a photosensitive polymer. The photosensitive polymer may include photosensitive polyimide, photosensitive polybenzoxazole (PBO), epoxy, benzocyclobutene (BCB), and the like.

As the wall layer 210 has a height sufficient to prevent the upper electrode 140, which moves in response to the vibration of the piezoelectric layer 130, from coming into contact with the first roof layer 220, a cavity may be formed between the BAW filter 100 and the package structure 200.

The first roof layer 220 is a plate-shaped structure layer formed in the horizontal direction on the upper portion of the wall layer 210. The first roof layer 220 is formed above the wall layer 210 to protect the BAW filter 100. The end of the first roof layer 220 may form the same plane as the lateral end of the wall layer 210, or it may protrude further in the lateral direction beyond the lateral end of the wall layer 210.

The first roof layer 220 may be formed of a photosensitive polymer. Such a photosensitive polymer may include photosensitive polyimide, photosensitive polybenzoxazole (PBO), epoxy, and the like.

The second roof layer 230 is a layer formed on the upper and lateral portions of the first roof layer 220 to protect the BAW filter 100. To this end, the second roof layer 230 is a layer formed to surround the lateral portion of the wall layer 210 and the upper portion of the first roof layer 220.

That is, the second roof layer 230 includes an upper pattern 230-1 formed to surround the upper portion of the first roof layer 220, and a lateral pattern 230-2 formed to surround the lateral portion of the wall layer 210.

The upper pattern 230-1 of the second roof layer 230 includes a plate-shaped form that extends in the horizontal direction on the upper portion of the first roof layer 220. In addition, the lateral pattern 230-2 of the second roof layer 230 extends downward along the lateral portion of the wall layer 210 and includes an outer wall shape formed to be in contact with the piezoelectric layer 130 and the electrode pad 150 of the BAW filter 100. Accordingly, the second roof layer 230 may have a structure that surrounds both the outer surface of the first roof layer 220 and the wall layer 210.

The second roof layer 230 may also be formed of a photosensitive polymer such as photosensitive polyimide, photosensitive polybenzoxazole (PBO), epoxy, or the like.

As described above, the first roof layer 220 and the second roof layer 230 may be formed of photosensitive polymer materials, but they may be formed of different polymer materials among the photosensitive polymers. For example, if the first roof layer 220 is made of photosensitive polyimide, the second roof layer 230 may be made of photosensitive polybenzoxazole (PBO).

In addition, even if the first roof layer 220 and the second roof layer 230 are formed of the same photosensitive polymer material, some of their inherent properties (e.g., elastic modulus, tensile strength, absorption rate, molecular weight, coefficient of linear expansion, thermal conductivity, weather resistance, heat resistance, etc.) may differ to some extent. For example, even if both the first roof layer 220 and the second roof layer 230 are made of photosensitive polyimide, the first roof layer 220 may be a photosensitive polyimide having a first tensile strength, while the second roof layer 230 may be a photosensitive polyimide having a second tensile strength.

The redistribution layer 240 is a layer formed on one side of the second roof layer 230 to electrically connect the package structure 200 and the BAW filter 100. The redistribution layer 240 connects the second roof layer 230, which constitutes the package structure 200, and the electrode pad 150 formed on the BAW filter 100. To this end, the redistribution layer 240 is formed of a conductive metal material, for example, a metal such as Cu, Ni, Au, or Sn.

The redistribution layer 240 is formed along the lateral portion of the second roof layer 230. In addition, one end of the redistribution layer 240 is formed in the horizontal manner on the upper surface of the second roof layer 230, and the other end is connected to the electrode pad 150 formed on the BAW filter 100.

As shown in FIG. 1, one end of the redistribution layer 240 is formed in contact with the upper surface of the second roof layer 230, and the other end of the redistribution layer 240 is connected to the electrode pad 150 formed on the lower electrode 120 of the BAW filter 100.

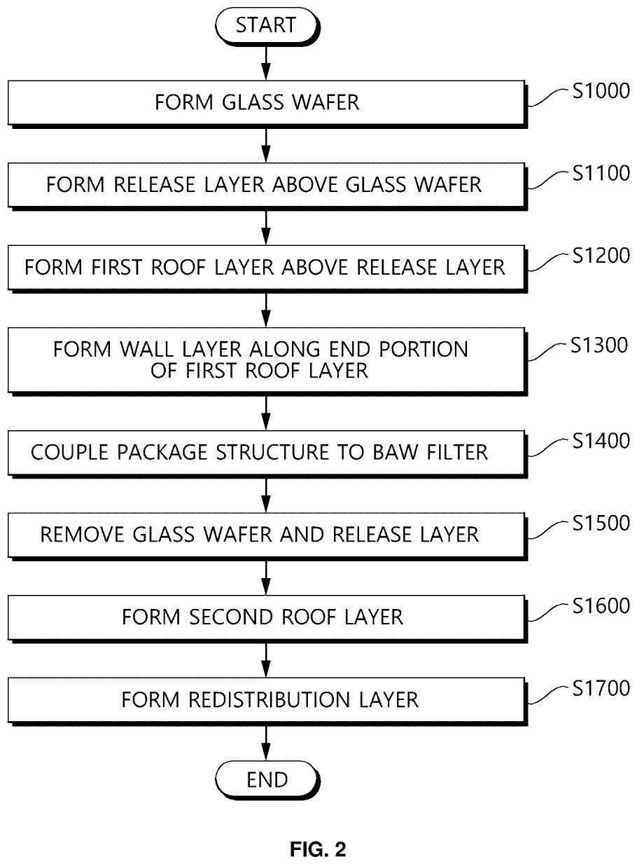

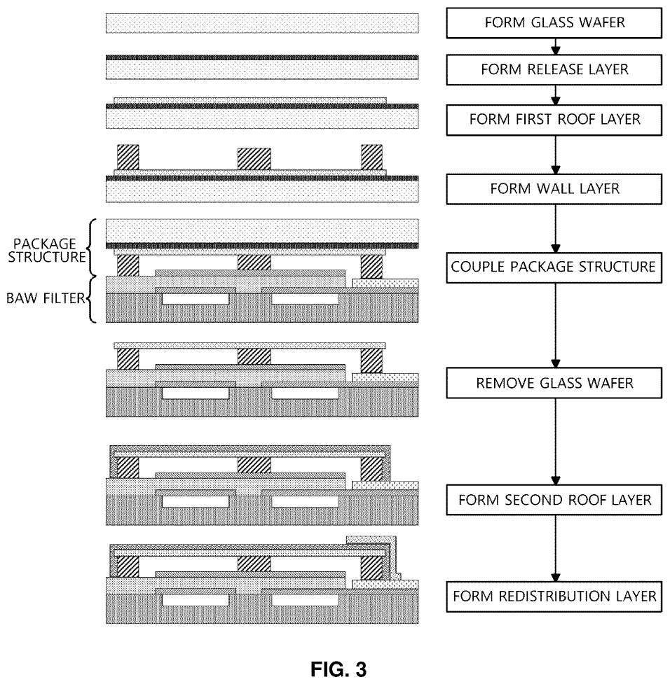

FIG. 2 is a flowchart illustrating one embodiment of a method of manufacturing a BAW package according to the present invention, and FIG. 3 illustrates the step-by-step structures of a BAW package formed through the manufacturing method shown in FIG. 2.

First, a glass wafer for a package structure is formed (step S1000). The glass wafer may be made of borosilicate glass, which has a thermal expansion coefficient similar to silicon and allows laser wavelengths to pass through.

After step S1000, a release layer is formed above the glass wafer (step S1100). The release layer is used for the later removal of the glass wafer. The release layer may be made of a polymer material that reacts with a laser, causing its polymer bonds to break.

After step S1100, a first roof layer is formed above the release layer (step S1200). The first roof layer may be formed of a photosensitive polymer. Such a photosensitive polymer may include photosensitive polyimide, photosensitive polybenzoxazole (PBO), epoxy, benzocyclobutene (BCB), and the like.

After step S1200, a wall layer is formed that extends in the vertical direction along the end portion of the first roof layer, thereby taking the form of an outer wall (step S1300). The wall layer may also be formed of a photosensitive polymer, similar to the first roof layer.

The wall layer may be formed by vertically extending along the end portion of the first roof layer, and thus may take the form of an outer wall (210-1 in FIG. 1) that surrounds the roof layer. Additionally, it may include a partition wall form (210-2 in FIG. 1) that extends vertically in a region crossing the central portion of the first roof layer. The minimum height of the wall layer may be such that the upper electrode, which moves in response to the vibration of the piezoelectric layer, does not come into contact with the first roof layer.

After step S1300, the package structure including the first roof layer and the wall layer is coupled to a BAW filter (step S1400). The wall layer of the package structure is coupled to the piezoelectric layer or upper electrode, which constitutes the BAW filter.

Referring to FIGS. 1 and 3, the wall layer formed at the end portion of the first roof layer is coupled at its end to the upper surface of the piezoelectric layer and the upper surface of the electrode pad, which constitute the BAW filter. The wall layer formed at the central portion of the first roof layer is coupled at its end to the upper surface of the upper electrode, which constitutes the BAW filter. At this time, the photosensitive polymer constituting the wall layer may be bonded to the piezoelectric layer and the upper electrode of the BAW filter through adhesion.

After step S1400, the glass wafer and the release layer are removed from the package structure (step S1500). The glass wafer may be separated by irradiating the release layer with a laser to break its polymer bonds, and the remaining release layer left on the roof layer may then be removed using a wet solution or ashing.

After step S1500, a second roof layer is formed to surround the first roof layer and the wall layer, which constitute the package structure (step S1600). The second roof layer is formed to protect the first roof layer and the wall layer.

The second roof layer is formed above the first roof layer from which the glass wafer and the release layer have been removed in the package structure. In addition to being formed above the first roof layer, the second roof layer is also formed to surround the later portion of the wall layer. The second roof layer is formed in a plate shape extending in the horizontal direction on the upper portion of the first roof layer, and also extends downward along the lateral portion of the wall layer to be in contact with the piezoelectric layer and the electrode pad of the BAW filter. Accordingly, the second roof layer may have a structure that surrounds the outer surfaces of the first roof layer and the wall layer. The second roof layer may also be formed of a photosensitive polymer such as photosensitive polyimide, photosensitive polybenzoxazole (PBO), epoxy, or the like.

After step S1600, a redistribution layer is formed to electrically connect the package structure and the BAW filter (step S1700). The redistribution layer is formed along the upper and lateral surfaces of the second roof layer. At this time, one end of the redistribution layer is connected to the upper surface of the second roof layer, and the other end is connected to the electrode pad formed on the BAW filter.

Referring to FIGS. 1 to 3, one end of the redistribution layer is connected in a state of horizontal contact with the upper surface of the roof layer, and the other end of the redistribution layer is connected in a state of horizontal contact with the upper surface of the electrode pad, which is formed on the lower electrode of the BAW filter.

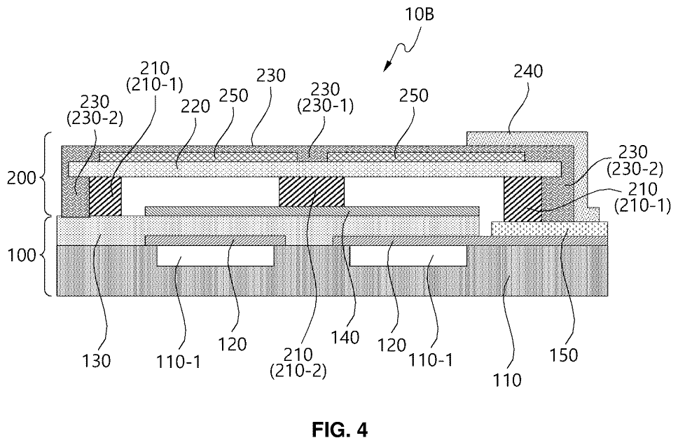

FIG. 4 is a cross-sectional side view illustrating a BAW package 10B according to another embodiment of the present invention.

Referring to FIG. 4, a BAW package 10B includes a BAW filter 100 and a package structure 200.

The BAW filter 100 includes a substrate 110, a lower electrode 120, a piezoelectric layer 130, an upper electrode 140, and an electrode pad 150. The detailed description of the BAW filter 100 is the same as that of the BAW package 10A, and thus a detailed description will be omitted.

The package structure 200 is a structure that serves to protect the BAW filter 100. To this end, the package structure 200 includes a wall layer 210, a first roof layer 220, a second roof layer 230, a redistribution layer 240, and a reinforcement layer 250.

Among the components of the package structure 200, the details of the wall layer 210, the first roof layer 220, the second roof layer 230, and the redistribution layer 240 are the same as those of the BAW package 10A, and therefore, detailed descriptions thereof will be omitted.

However, the BAW package 10B of FIG. 4 differs from the BAW package 10A of FIG. 1 in that a reinforcement layer 250 is additionally provided. Accordingly, only the reinforcement layer 250 will be described below.

The reinforcement layer 250 is a layer for supporting the shape of the first roof layer 220. The reinforcement layer 250 may be a plate-shaped structure formed in the horizontal direction on the upper portion of the first roof layer 220. Accordingly, the reinforcement layer 250 may be positioned between the first roof layer 220 and the second roof layer 230.

One reinforcement layer 250 may be formed, or two or more reinforcement layers 250 may be arranged at intervals. By forming the reinforcement layer 250, the first roof layer 220 and the second roof layer 230 may be robustly supported, thereby enhancing the protective function for the BAW filter 100. The reinforcement layer may use a metallic material to improve the rigidity of the roof layers.

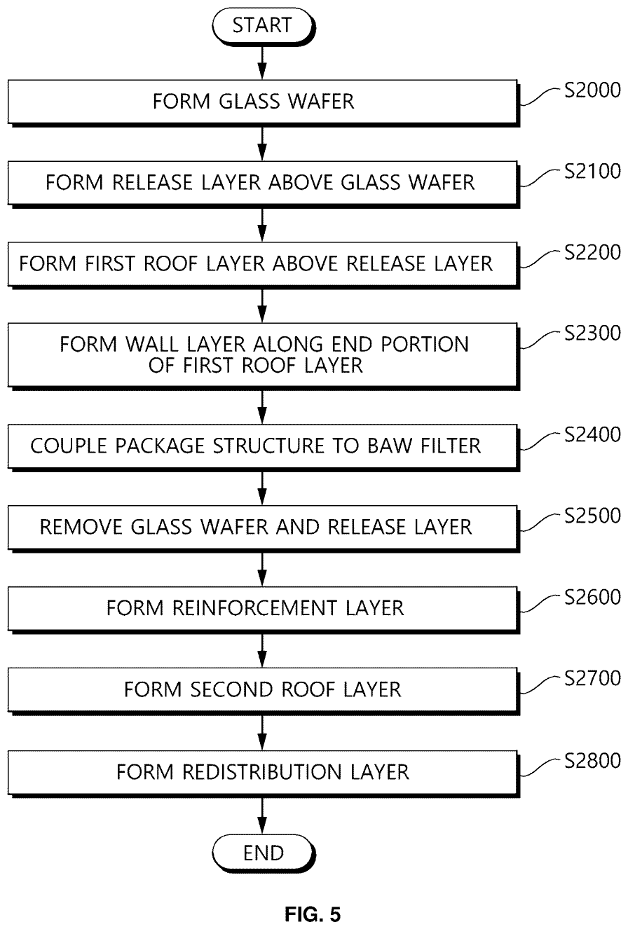

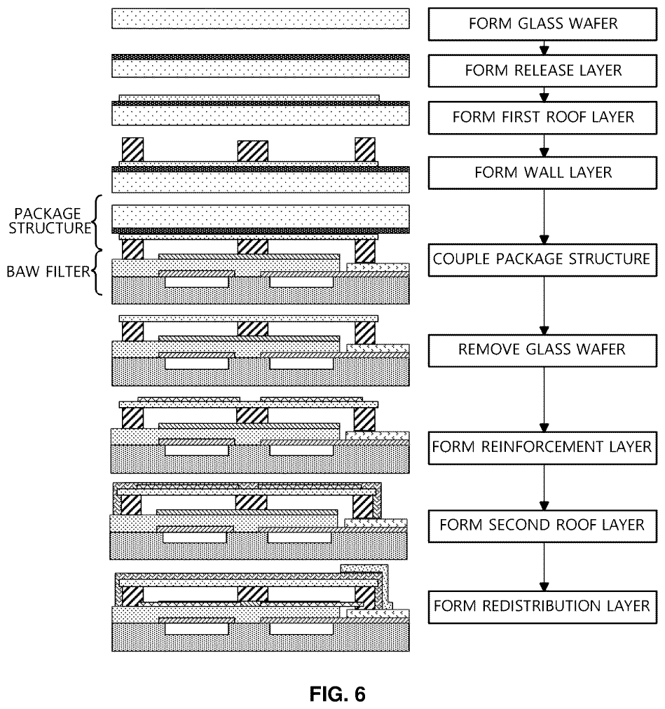

FIG. 5 is a flowchart illustrating another embodiment of a method of manufacturing a BAW package according to the present invention, and FIG. 6 illustrates the step-by-step structures of a BAW package formed through the manufacturing method shown in FIG. 5. The descriptions of the BAW package manufacturing method shown in FIG. 5 that overlap with the contents of FIG. 1 will be omitted.

First, a glass wafer for a package structure is formed (step S2000).

After step S2000, a release layer is formed above the glass wafer (step S2100).

After step S2100, a first roof layer is formed above the release layer (step The first roof layer may be formed of a photosensitive polymer. S2200).

After step S2200, a wall layer is formed that extends in the vertical direction along the end portion of the first roof layer, thereby taking the form of an outer wall (step S2300). The wall layer may also be formed of a photosensitive polymer, similar to the first roof layer.

After step S2300, a package structure including the first roof layer and the wall layer is coupled to a BAW filter (step S2400). The wall layer of the package structure is coupled to a piezoelectric layer or upper electrode, which constitutes the BAW filter.

After step S2400, the glass wafer and the release layer are removed from the package structure (step S2500).

After step S2500, a reinforcement layer is formed above the first roof layer to support the first roof layer and the second roof layer (step S2600). The reinforcement layer may be a plate-shaped structure formed in the horizontal direction on the upper portion of the first roof layer. One reinforcement layer may be formed, or two or more reinforcement layers may be arranged at intervals.

After step S2600, a second roof layer is formed to surround the first roof layer, the wall layer, and the reinforcement layer (step S2700). The second roof layer is formed to protect the first roof layer, the wall layer, and the reinforcement layer.

The second roof layer is formed to surround the upper portions of the first roof layer and the reinforcement layer and the later portion of the wall layer. The second roof layer is formed in a plate shape extending in the horizontal direction on the upper portion of the first roof layer, and also extends downward along the lateral portion of the wall layer to be in contact with the piezoelectric layer and the electrode pad of the BAW filter.

After step S2700, a redistribution layer is formed to electrically connect the package structure and the BAW filter (step S2800). The redistribution layer is formed along the upper and lateral surfaces of the second roof layer. At this time, one end of the redistribution layer is connected to the upper surface of the second roof layer, and the other end is connected to the electrode pad formed on the BAW filter.

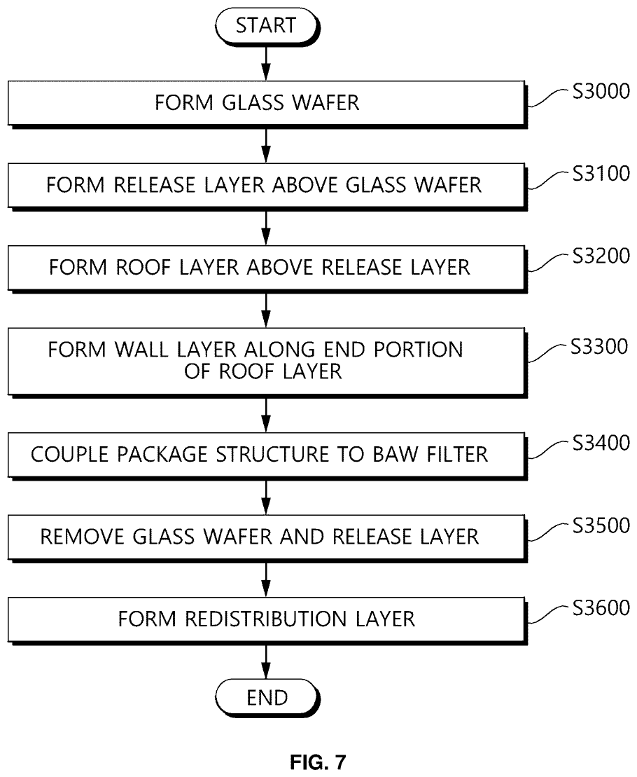

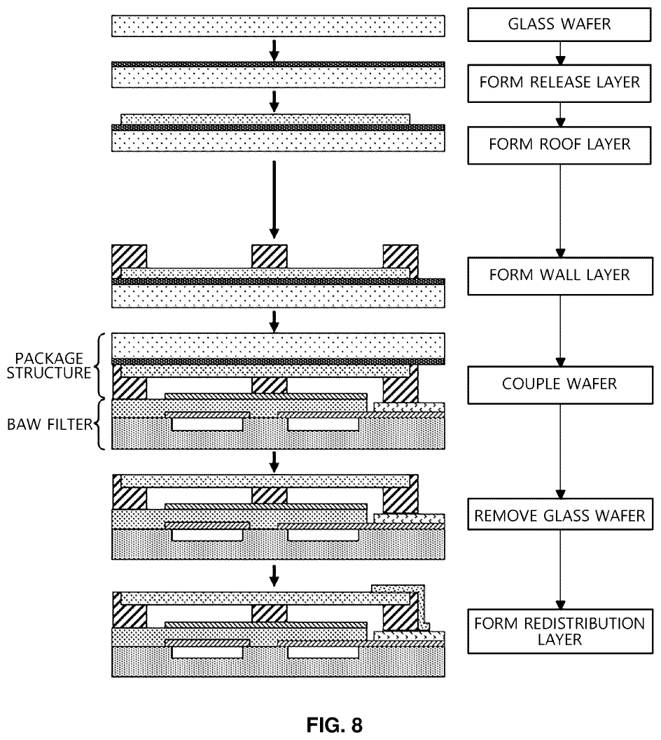

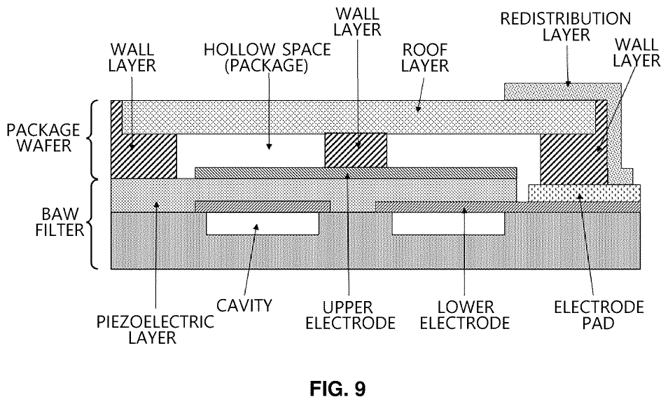

FIG. 7 is a flowchart illustrating yet another embodiment of a method of manufacturing a BAW package according to the present invention, and FIG. 8 illustrates the step-by-step structures of a BAW package formed through the manufacturing method shown in FIG. 7. In addition, FIG. 9 illustrates a BAW package formed by the manufacturing method shown in FIG. 7.

First, a glass wafer for a package structure is formed (step S3000).

After step S3000, a release layer is formed above the glass wafer (step S3100). The release layer is used for the later removal of the glass wafer.

After step S3100, a first roof layer is formed above the release layer (step S3200). The roof layer may be formed of a photosensitive polymer.

After step S3200, a wall layer is formed that extends vertically along the end portion of the roof layer and surrounds the roof layer, thereby completing the package structure (step S3300). The wall layer may also be formed of a photosensitive polymer, similar to the roof layer.

The wall layer may be formed by vertically extending along the end portions of the lateral surfaces of the roof layer, and thus may take the form of an outer wall that surrounds the roof layer. Additionally, the wall layer may include a partition wall form that extends vertically in a region crossing the central portion of the roof layer, rather than along the end portions of the later surfaces of the roof layer. The minimum height of the wall layer may be such that the upper electrode, which moves in response to the vibration of the piezoelectric layer, does not come into contact with the roof layer.

After step S3300, the package structure is coupled to a BAW filter including a substrate, a lower electrode, a piezoelectric layer, and an upper electrode (step S3400).

The wall layer may be coupled to the piezoelectric layer or upper electrode, which constitutes the BAW filter. Referring to FIG. 9, the wall layer formed at the end portions of the later surfaces of the roof layer is joined at its end to the upper surface of the piezoelectric layer, which constitute the BAW filter. The wall layer formed at the central portion of the roof layer is coupled at its end to the upper surface of the upper electrode, which constitutes the BAW filter. At this time, the photosensitive polymer constituting the wall layer may be bonded to the piezoelectric layer and the upper electrode of the BAW filter through adhesion.

After step S3400, the glass wafer and the release layer are removed from the package structure (step S3500).

After step S3500, a redistribution layer is formed on the package structure (step S3600). The redistribution layer may be formed along later surface portions of the roof layer, and have one end connected to one side of the roof layer and the other end connected to an electrode pad formed on the substrate of the BAW filter. The redistribution layer is formed of a conductive metal material.

Referring to FIG. 9, the redistribution layer is formed vertically along the lateral portion of the wall layer. One end of the redistribution layer is connected in a state of horizontal contact with the upper surface of the roof layer, and the other end is connected in a state of horizontal contact with the upper surface of the electrode pad formed on the substrate of the BAW filter.

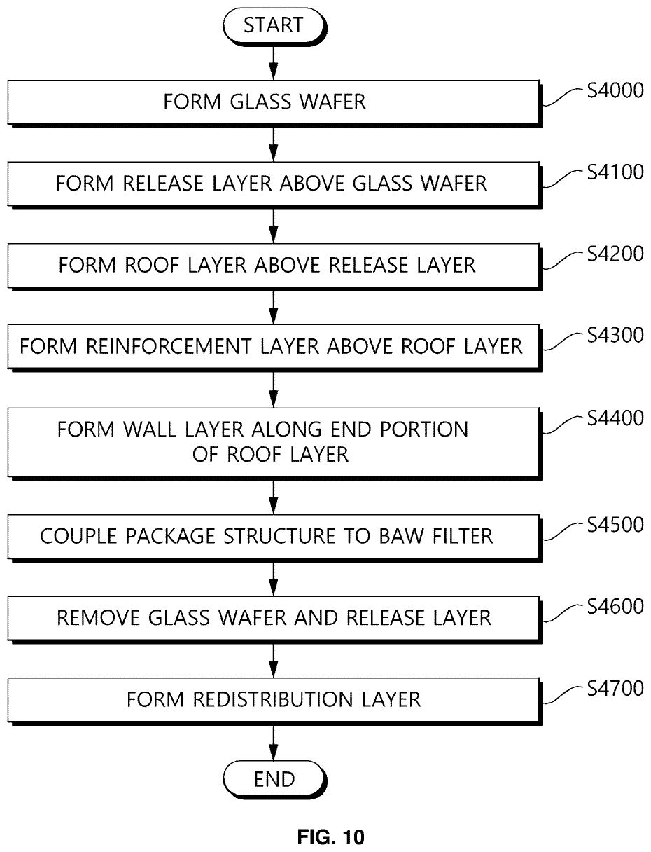

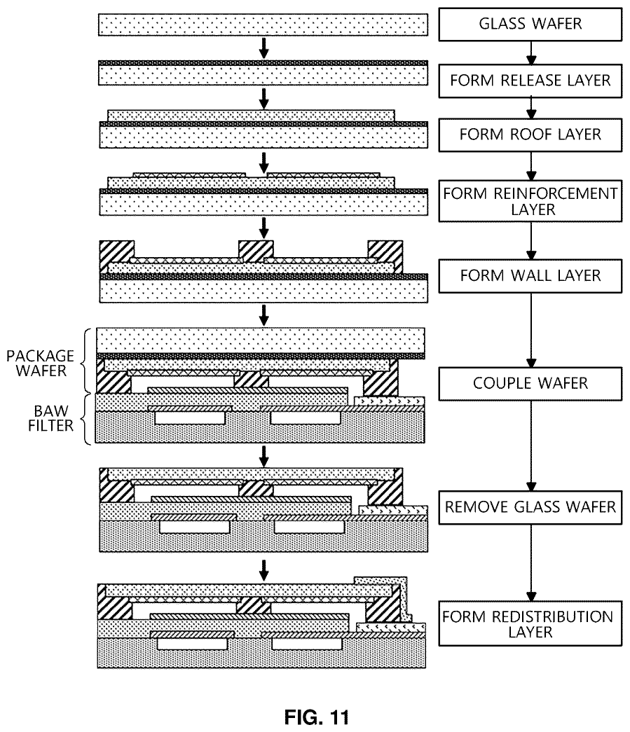

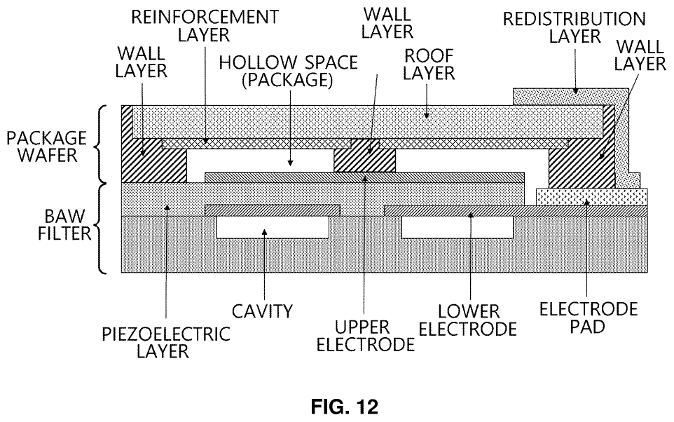

FIG. 10 is a flowchart illustrating still another embodiment of a method of manufacturing a BAW package according to the present invention, and FIG. 11 illustrates the step-by-step structures of a BAW package formed through the manufacturing method shown in FIG. 10. In addition, FIG. 12 illustrates a BAW package formed by the manufacturing method shown in FIG. 10.

First, a glass wafer for a package structure is formed (step S4000).

After step S4000, a release layer is formed above the glass wafer (step S4100). The release layer is used for the later removal of the glass wafer.

After step S4100, a roof layer is formed above the release layer (step S4200). The roof layer may be formed of a photosensitive polymer.

After step S4200, at least one reinforcement layer is formed above the roof layer (step S4300). The reinforcement layer is a layer for supporting the shape of the roof layer.

After step S4300, a wall layer is formed that extends vertically along the end portions of the roof layer and surrounds the roof layer, thereby completing the package structure (step S4400). The wall layer may be formed by vertically extending along the end portions of the lateral surfaces of the roof layer, and thus may take the form of an outer wall that surrounds the roof layer.

After step S4400, the package structure is coupled to a BAW filter including a substrate, a lower electrode, a piezoelectric layer, and an upper electrode (step S4500). The wall layer may be coupled to the piezoelectric layer or upper electrode, which constitutes the BAW filter.

After step S4500, the glass wafer and the release layer are removed from the package structure (step S4600).

After step S4600, a redistribution layer is formed on the package structure (step S4700). The redistribution layer may be formed along later surface portions of the roof layer, and have one end connected to one side of the roof layer and the other end connected to an electrode pad formed on the substrate of the BAW filter. The redistribution layer is formed of a conductive metal material.

The exemplary embodiments of the present invention have been described above. One of ordinary skill in the art may understand that modifications may be made without departing from the scope of the present invention. Therefore, the disclosed embodiments should be considered in a descriptive aspect not a limitative aspect. The scope of the present invention will be shown in the claims not in the foregoing description, and all differences within an equivalent scope thereof should be construed as being included in the present invention.

### REFERENCE NUMERALS

10A, 10B: BAW PACKAGE

100: BAW FILTER

200: PACKAGE STRUCTURE

210: WALL LAYER

220: FIRST ROOF LAYER

230: SECOND ROOF LAYER

240: REDISTRIBUTION LAYER

250: REINFORCEMENT LAYER

What is claimed:

1. A bulk acoustic wave (BAW) package comprising:
a BAW filter comprising a substrate having at least one cavity on an upper surface thereof, a lower electrode formed above the substrate, a piezoelectric layer formed above the lower electrode, and an upper electrode formed above the piezoelectric layer; and
a package structure formed above the BAW filter to protect the BAW filter,
wherein the package structure comprises
a wall layer extending in a vertical direction to surround a peripheral portion of the BAW filter;
a first roof layer having a plate-shaped structure formed in a horizontal direction on an upper portion of the wall layer;
a second roof layer formed to surround a lateral portion of the wall layer and an upper portion of the first roof layer; and
a redistribution layer formed on one side of the second roof layer in order to electrically connect the package structure and the BAW filter.

2. The BAW package of claim 1, wherein the wall layer, the first roof layer, and the second roof layer are each formed of a photosensitive polymer.

3. The BAW package of claim 1, wherein the wall layer includes a partition wall extending in the vertical direction on an upper portion of the upper electrode.

4. The BAW package of claim 1, further comprising a reinforcement layer formed between the first roof layer and the second roof layer and configured to support the first roof layer and the second roof layer.

5. The BAW package of claim 1, wherein the redistribution layer is formed on one side of the second roof layer and connects an electrode pad formed on the BAW filter and an upper portion of the second roof layer.

6. A method of manufacturing a bulk acoustic wave (BAW) filter, comprising:
forming a glass wafer;
forming a release layer above the glass wafer;
forming a first roof layer above the release layer;
forming a wall layer that extends vertically along end portion of the roof layer and surrounds the first roof layer, thereby completing a package structure;
coupling the package structure to a BAW filter that comprises a substrate, a lower electrode, a piezoelectric layer, and an upper electrode;
removing the glass wafer and the release layer from the package structure;
forming a second roof layer to surround a lateral portion of the wall layer and an upper portion of the first roof layer; and
forming a redistribution layer for electrically connecting the package structure and the BAW filter.

7. The method of claim 6, wherein the wall layer, the first roof layer, and the second roof layer are each formed of a photosensitive polymer.

8. The method of claim 6, wherein the forming of the wall layer comprises forming a partition wall that extends in the vertical direction on an upper portion of the upper electrode.

9. The method of claim 6, further comprising forming a reinforcement layer above the first roof layer to support the first roof layer and the second roof layer after removing the glass wafer and the release layer from the package structure.

10. The method of claim 6, wherein the forming of the redistribution layer comprises forming the redistribution layer on one side of the second roof layer wherein the redistribution layer connects an electrode pad formed on the BAW filter and an upper portion of the second roof layer.
